(19) United States
(12) Patent Application Publication
(10) Pub. No.: US 2026/0206128 A1
(43) Pub. Date: Jul. 16, 2026

(54) CIRCUIT ELEMENT, ELECTRONIC PACKAGING ELEMENT AND CIRCUIT BOARD ASSEMBLY

(71) Applicant: NATIONAL TSING HUA UNIVERSITY, Hsinchu (TW)

(72) Inventors: Sheng-Shian LI, Hsinchu (TW); Zhong-Wei Lin, Hsinchu (TW)

(21) Appl. No.: 19/385,178

(22) Filed: Nov. 11, 2025

Related U.S. Application Data
(60) Provisional application No. 63/745,325, filed on Jan. 15, 2025.

(30) Foreign Application Priority Data
Aug. 1, 2025 (TW) 114129449

(51) Int. Cl. H05K 1/02; H05K 1/11

(52) U.S. Cl. CPC H05K 1/023; H05K 1/119; H05K 2201/09418; H05K 2201/10068

(57) ABSTRACT

A circuit element includes a first electrode, a first connection line, a fourth connection line, a first load, a second electrode and a third connection line. The first connection line, the fourth connection line and the first load are electrically connected in sequence, and the first connection line and the fourth connection line are electrically connected to form a first path. The third connection line is at least a part of a second path. The first connection line and the third connection line are configured for respectively inputting a signal to the circuit element and outputting a signal therefrom, and at least one line segment of the first path and at least one line segment of the second path are not perpendicular to each other.

### RELATED APPLICATIONS

This application claims priority to US Provisional Application Serial Number 63/745,325, filed January 15, 2025, and Taiwan Application Serial Number 114129449, filed August 1, 2025, which are herein incorporated by reference.

### BACKGROUND

### Technical Field

The present disclosure relates to a circuit element, an electronic packaging element and a circuit board assembly. More particularly, the present disclosure relates to a circuit element, an electronic packaging element and a circuit board assembly, which include two coupling electrodes.

### Description of Related Art

Today's circuit elements, electronic packaging elements, and circuit board assemblies often include two coupling electrodes, such as resonators, oscillators, switches, capacitors, etc., and these elements also need to continuously improve their electrical functions, such as reducing feedthrough signal and improving signal-to-background ratios, to meet people's needs for technological development.

Hence, in the current market of circuit elements, electronic packaging elements, and circuit board assemblies including two coupling electrodes, there is an urgent need to develop a circuit element, electronic packaging element and circuit board assembly that can reduce feedthrough signal, improve signal-to-background ratios, and at the same time reduce costs, space, and element design complexity.

### SUMMARY

According to one aspect of the present disclosure, a circuit element includes a first electrode, a first connection line, a fourth connection line, a first load, a second electrode and a third connection line. The first connection line is electrically connected to the first electrode. The fourth connection line is electrically connected to the first electrode. The first connection line, the fourth connection line and the first load are electrically connected in sequence, and the first connection line and the fourth connection line are electrically connected to form a first path. The second electrode is separated from and coupled to the first electrode. The third connection line is electrically connected to the second electrode, and the third connection line is at least a part of a second path. The first connection line and the third connection line are configured for respectively inputting a signal to the circuit element and outputting a signal therefrom, and at least one line segment of the first path and at least one line segment of the second path are not perpendicular to each other.

According to another aspect of the present disclosure, an electronic packaging element includes a packaging substrate, a chip, a first connection line, a fourth connection line, a first pin, a fourth pin, a third connection line and a third pin. The chip is disposed on the packaging substrate and includes a first electrode and a second electrode, and the second electrode is separated from and coupled to the first electrode. The first connection line is electrically connected to the first electrode. The fourth connection line is electrically connected to the first electrode, and the first connection line and the fourth connection line are electrically connected to form a first path. The first pin is disposed on the packaging substrate, and the first pin, the first connection line and the first electrode are electrically connected in sequence. The fourth pin is disposed on the packaging substrate, and the first electrode, the fourth connection line and the fourth pin are electrically connected in sequence. The third connection line is electrically connected to the second electrode, and the third connection line is at least a part of a second path. The third pin is disposed on the packaging substrate, and the second electrode, the third connection line and the third pin are electrically connected in sequence. The first pin, the third pin and the fourth pin are configured to be electrically connected to a circuit board, the first pin and the third pin are configured for respectively inputting a signal to the electronic packaging element and outputting a signal therefrom, and at least one line segment of the first path and at least one line segment of the second path are not perpendicular to each other.

According to further another aspect of the present disclosure, a circuit board assembly includes a circuit board, a chip, a first connection line, a fourth connection line and a third connection line. The chip is disposed on the circuit board and includes a first electrode and a second electrode, and the second electrode is separated from and coupled to the first electrode. The first connection line is electrically connected to the first electrode. The fourth connection line is electrically connected to the first electrode, and the first connection line and the fourth connection line are electrically connected to form a first path. The third connection line is electrically connected to the second electrode, and the third connection line is at least a part of a second path. The first connection line, the third connection line and the fourth connection line are disposed on the circuit board, the first connection line and the third connection line are configured for respectively inputting a signal to the circuit board assembly and outputting a signal therefrom, and at least one line segment of the first path and at least one line segment of the second path are not perpendicular to each other.

### BRIEF DESCRIPTION OF THE DRAWINGS

The present disclosure can be more fully understood by reading the following detailed description of the embodiment, with reference made to the accompanying drawings as follows:

FIG. 1A is a schematic view of a circuit element according to the first embodiment of the present disclosure.

FIG. 1B is a three-dimensional schematic view of a part of the circuit element in FIG. 1A.

FIG. 1C is a schematic view of an equivalent circuit of the circuit element in FIG. 1A.

FIG. 1D is a schematic view of a current of the circuit element in FIG. 1A.

FIG. 1E is a schematic view of admittance parameters corresponding to different equivalent resistances of the first load of the circuit element in FIG. 1A.

FIG. 1F is another schematic view of admittance parameters corresponding to different equivalent resistances of the first load of the circuit element in FIG. 1A.

FIG. 1G is a schematic view of admittance parameters of the circuit element in FIG. 1A and a conventional circuit element in FIG. 5A.

FIG. 2A is a schematic view of an electronic packaging element according to the second embodiment of the present disclosure.

FIG. 2B is a schematic view of admittance parameters of the electronic packaging element in FIG. 2A.

FIG. 3 is a schematic view of a circuit board assembly according to the third embodiment of the present disclosure.

FIG. 4A is a schematic view of a circuit element according to the first example of the fourth embodiment of the present disclosure.

FIG. 4B is a schematic view of a circuit element according to the second example of the fourth embodiment of the present disclosure.

FIG. 5A is a schematic view of the conventional circuit element.

FIG. 5B is a schematic view of a conventional electronic packaging element.

FIG. 5C is a schematic view of a conventional circuit board assembly.

### DETAILED DESCRIPTION

Embodiments of the present disclosure will be described below with reference to the drawings. For the sake of clarity, many practical details will be explained together in the following statements. However, it should be understood that these practical details should not be used to limit the present disclosure. That is, these practical details are not necessary in embodiments of the present disclosure. In addition, for the sake of simplifying the drawings, some commonly used structures and components are shown in the drawings in a simple schematic manner; and repeated components may be represented by the same numbers.

In addition, the terms first, second, etc. are used herein to describe various elements or components, these elements or components should not be limited by these terms. Consequently, a first element or component discussed below could be termed a second element or component. Moreover, the combination of components in the present disclosure is not a combination that is generally known, conventional or customary in this field. The components themselves being or being not common knowledge cannot be used to determine whether the combination relationship can be easily completed by a person skilled in the technical field.

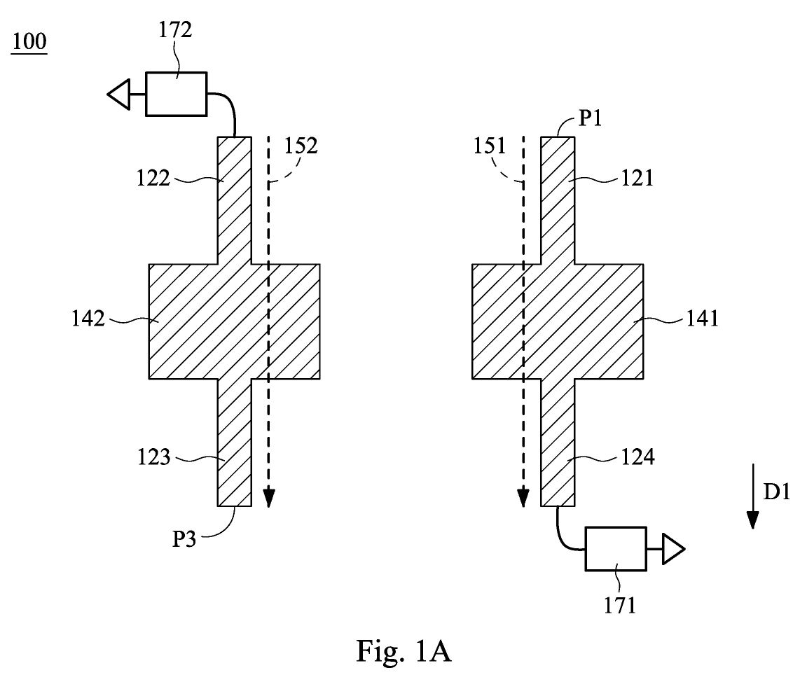

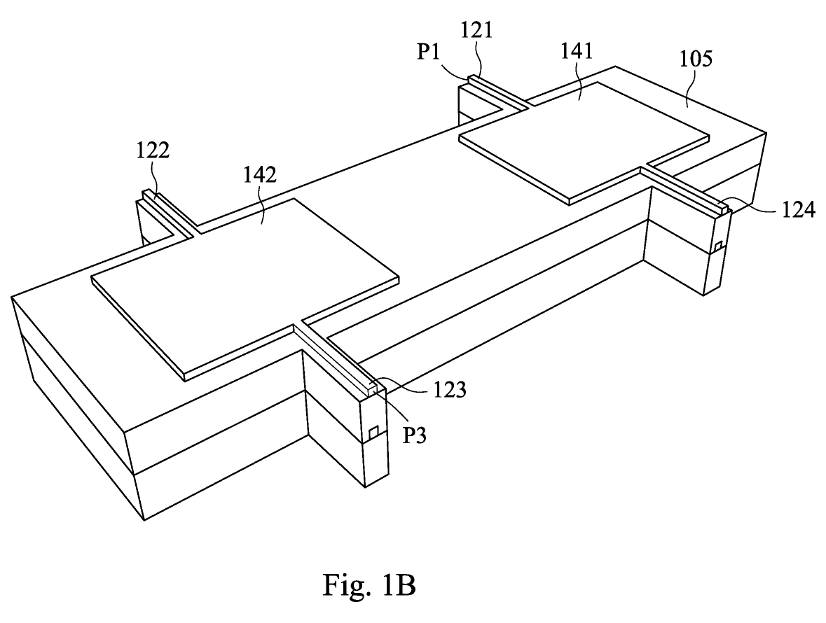

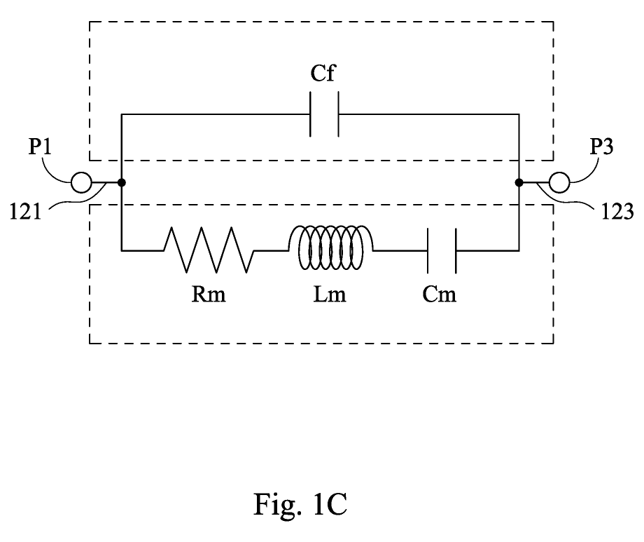

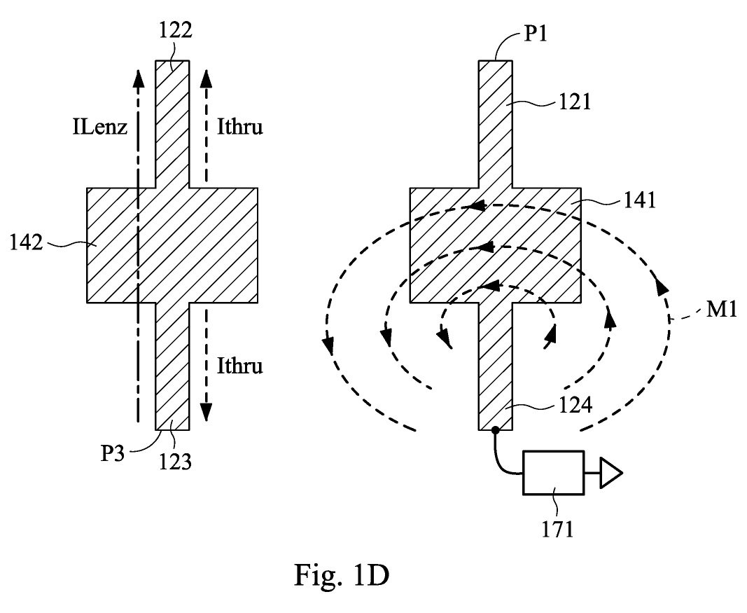

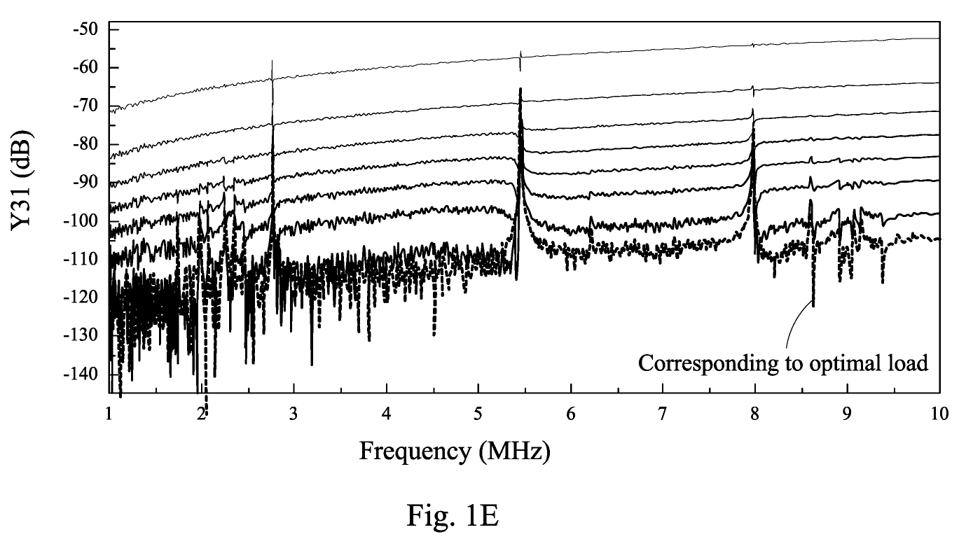

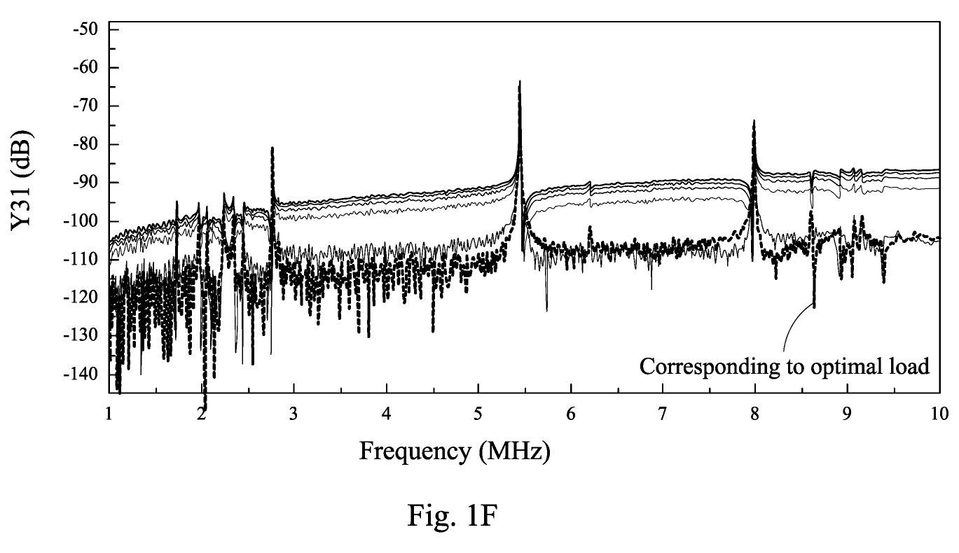

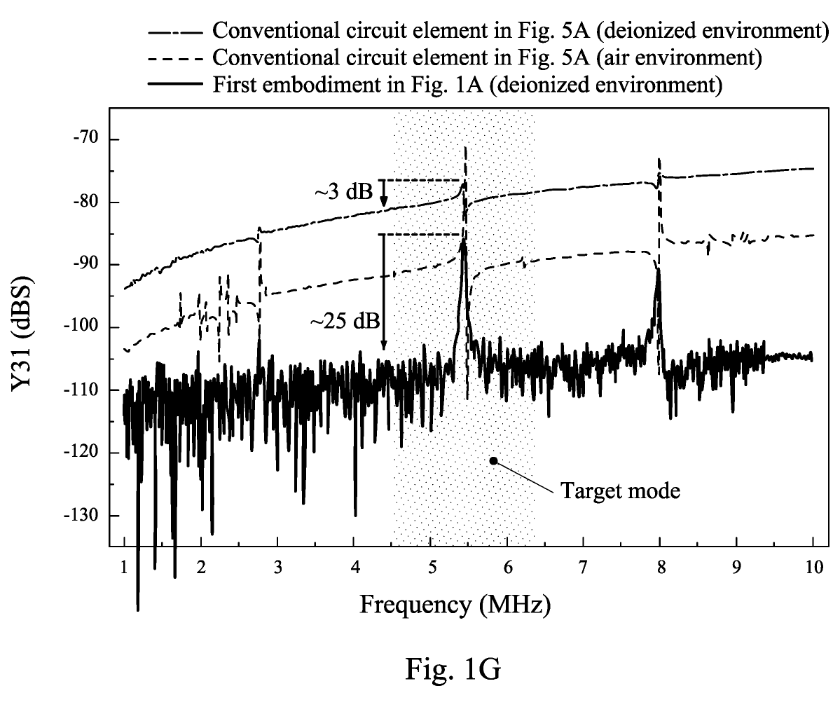

FIG. 1A is a schematic view of a circuit element 100 according to the first embodiment of the present disclosure, and FIG. 1B is a three-dimensional schematic view of a part of the circuit element 100 in FIG. 1A. With reference to FIG. 1A and FIG. 1B, the circuit element 100 includes a first electrode 141, a first connection line 121, a fourth connection line 124, a first load 171, a second electrode 142 and a third connection line 123.

The first connection line 121 is electrically connected (in series) to the first electrode 141. The fourth connection line 124 is electrically connected to the first electrode 141. The first connection line 121, the fourth connection line 124 and the first load 171 are electrically connected in sequence, and the first connection line 121 and the fourth connection line 124 are electrically connected to form a first path 151 (i.e., a path electrically connected from the first connection line 121 to the fourth connection line 124 forms the first path 151). The second electrode 142 is separated from and coupled to the first electrode 141. The third connection line 123 is electrically connected to the second electrode 142, and the third connection line 123 is at least a part of a second path 152. The first connection line 121 and the third connection line 123 are configured for respectively inputting a signal to the circuit element 100 and outputting a signal therefrom, and at least one line segment of the first path 151 and at least one line segment of the second path 152 are not perpendicular to each other. Therefore, the circuit element 100 including two coupling electrodes of the present disclosure is designed according to a feedthrough elimination method based on the interconnect magnetic effect, thereby reducing feedthrough signal of the circuit element 100, that is, reducing the admittance outside the peak of the curve of FIG. 1G. Specifically, the present disclosure is advantageous in minimizing feedthrough signal by adjusting the impedance of the load terminator to adapt to changing conditions. Furthermore, the term “connect” described in the present disclosure refers to a directly or indirectly physical connection between two elements. The term “couple” described in the present disclosure refers to a separation between two elements without a physical connection, but rather the electric field energy generated by the current of one element excites the electric field energy of another element.

Compared to the conventional techniques (prior art), most research on magnetic phenomena has focused on sensing environmental changes, with few exploring the use of the magnetic effects of the structure itself to reduce unwanted signals. Alternatively, the conventional techniques have used virtual devices or differential structures, which require additional space or complex designs to reduce unwanted signals. The circuit element of the present disclosure designed in accordance with the feedthrough elimination method is advantageous in reducing element design complexity and can be expanded to and applied to various circuit elements including two coupling electrodes, such as MEMS (microelectromechanical system) resonators, but not limited to. Furthermore, the circuit element of the present disclosure can improve signal integrity in various environments without requiring complex redesign and can be seamlessly integrated into existing element design processes.

FIG. 1C is a schematic view of an equivalent circuit of the circuit element 100 in FIG. 1A. With reference to FIG. 1C, for the circuit element 100 including two coupling electrodes, such as a MEMS resonator, the equivalent circuit of the MEMS resonator includes a motion portion and a feedthrough portion. The motion portion includes a motion resistance Rm, a motion inductance Lm and a motion capacitance Cm in FIG. 1C, and the feedthrough portion includes a feedthrough capacitance Cf in FIG. 1C. With further reference to FIG. 1G, the peak of the curve of the admittance parameter Y31 is contributed by the motion portion, while the stopband (or floor), which excludes the peak of the curve of the admittance parameter Y31 and the frequencies surrounding it, is contributed by the feedthrough portion. For an ideal resonator, the admittance parameter Y31 in the stopband is required to be as small as possible, and suppressing the feedthrough capacitance Cf can help reduce the admittance parameter Y31.

FIG. 1D is a schematic view of a current of the circuit element 100 in FIG. 1A. With reference to FIG. 1D, it illustrates a physical explanation of the method proposed in the present disclosure for suppressing the feedthrough capacitance of the circuit element 100 (e.g., a resonator, etc.). The circuit element 100 includes at least two mutually coupling electrodes (i.e., the first electrode 141 and the second electrode 142). When an AC current is input from the input port P1, a feedthrough current Ithru is generated on the second connection line 122 and the third connection line 123. Furthermore, when the fourth connection line 124 is electrically connected to a terminal impedance (e.g., the first load 171), current flows through the first connection line 121 to the fourth connection line 124, so as to generate a magnetic field M1. According to Lenz's law, an induced current ILenz is generated on the third connection line 123 to the second connection line 122. The induced current ILenz has a current direction being opposite to the current on the first connection line 121 to the fourth connection line 124 and the feedthrough current Ithru on the third connection line 123. Therefore, the induced current ILenz on the third connection line 123 to the second connection line 122 offsets the feedthrough current Ithru of the third connection line 123, thereby reducing the feedthrough capacitance and the admittance parameter of the stopband.

In detail, with reference to FIG. 1A and FIG. 1B, the circuit element 100 may be a resonator. Therefore, the feedthrough signal of the resonator in the stopband can be reduced to improve its signal-to-background ratio. Specifically, the circuit element 100 may be a MEMS resonator. Furthermore, the circuit elements, electronic packaging elements and circuit board assemblies according to the present disclosure may be resonators, MEMS resonators, oscillators, switches, capacitors, or parts thereof, and the present disclosure is not limited thereto.

An included angle (not labeled in the drawings) between the at least one line segment of the first path 151 and the at least one line segment of the second path 152 may be between 0 degrees and 80 degrees. Therefore, the induced current ILenz flowing between the third connection line 123 and the second connection line 122 in FIG. 1D offsets at least a portion of the feedthrough current Ithru of the third connection line 123, thereby reducing the feedthrough capacitance and the admittance of the stopband. In addition, the included angle between the at least one line segment of the first path 151 and the at least one line segment of the second path 152 may be between 0 degrees and 45 degrees.

The at least one line segment of the first path 151 and the at least one line segment of the second path 152 may be parallel to each other. Therefore, the induced current ILenz flowing between the third connection line 123 and the second connection line 122 in FIG. 1D further offsets at least a portion of the feedthrough current Ithru of the third connection line 123, thereby further reducing the feedthrough capacitance and the admittance of the stopband. Specifically, the included angle between the entire first path 151 and the entire second path 152 is 0 degrees, that is, the entire first path 151 and the entire second path 152 are parallel to each other.

The circuit element 100 has a first direction D1, one end along the first direction D1 of the first electrode 141 may be electrically connected to the first connection line 121, and the other end along the first direction D1 of the second electrode 142 may be electrically connected to the third connection line 123. Therefore, it is advantageous in reducing feedthrough signal.

The circuit element 100 may further include a second connection line 122 and a second load 172. The second connection line 122 is electrically connected to the second electrode 142. The second load 172, the second connection line 122 and the third connection line 123 are electrically connected in sequence, and the second connection line 122 and the third connection line 123 are electrically connected to form the second path 152. Therefore, it is advantageous in reducing feedthrough signal and improving the application flexibility of the non-directional circuit element 100. Furthermore, one end of the load of the circuit element, the electronic packaging element and the circuit board assembly according to the present disclosure may be grounded.

The first connection line 121, the first electrode 141, the fourth connection line 124 and the first load 171 may be electrically connected in sequence, and the first connection line 121, the first electrode 141 and the fourth connection line 124 form the first path 151. The second load 172, the second connection line 122, the second electrode 142 and the third connection line 123 may be electrically connected in sequence, and the second connection line 122, the second electrode 142 and the third connection line 123 form the second path 152. Therefore, the feedthrough capacitance of the circuit element 100 can be reduced by the first path 151 and the second path 152 that are not perpendicular to each other.

The circuit element 100 may further include a substrate 105. Specifically, the first electrode 141, the second electrode 142, the first connection line 121, the second connection line 122, the third connection line 123 and the fourth connection line 124 are a conductive layout on the substrate 105. Therefore, the circuit element 100 of the present disclosure has a wide range of applications. According to the embodiment of the present disclosure, the substrate is a circuit carrier and can be a thin film piezoelectric-on-silicon (TPoS), a semiconductor substrate, a thin film substrate, a thick film substrate, a ceramic substrate, a printed circuit board (PCB), or a laser direct structuring (LDS) substrate, but the present disclosure is not limited thereto. Furthermore, all parts of each of the circuit elements, the electronic packaging elements and the circuit board assemblies of the present disclosure may be disposed on one surface layer, the other surface layer, an inner layer or a combination thereof of the substrate/packaging substrate/circuit board, and the specific structure or shape of the circuit configuration or conductive layout is not limited to the drawings disclosed herein.

An equivalent resistance of the first load 171 may be between 10 ohm and 1000 ohm, and an equivalent resistance of the second load 172 may be between 10 ohm and 1000 ohm. Therefore, the preferred equivalent resistances of the first load 171 and the second load 172 are beneficial to effectively reduce the admittance parameter of the stopband. Furthermore, according to the embodiment of the present disclosure, each of the first load and the second load is not limited to only one or more resistor elements.

FIG. 1E is a schematic view of admittance parameters Y31 corresponding to different equivalent resistances of the first load 171 of the circuit element 100 in FIG. 1A, FIG. 1F is another schematic view of admittance parameters Y31 corresponding to different equivalent resistances of the first load 171 of the circuit element 100 in FIG. 1A, and the admittance parameter Y31 can be measured by a vector network analyzer (VNA). With reference to FIG. 1A, FIG. 1E and FIG. 1F, the circuit element 100 including two coupling electrodes has the input port P1 and the output port P3, and the first load 171 and the second load 172 can be set to have the same equivalent resistance. The admittance parameter Y31 of the circuit element 100 changes with the equivalent resistances of the first load 171 and the second load 172. The curves from top to bottom in FIG. 1E correspond to equivalent resistances from 1 micro ohm to 65 ohm, respectively. The curves from top to bottom in FIG. 1F correspond to equivalent resistances from 200 ohm to 65 ohm, respectively. Hence, when the equivalent resistance of each of the first load 171 and the second load 172 is 65 ohm, it is the optimal load, and the circuit element 100 has the optimal, i.e., the lowest, admittance parameter Y31.

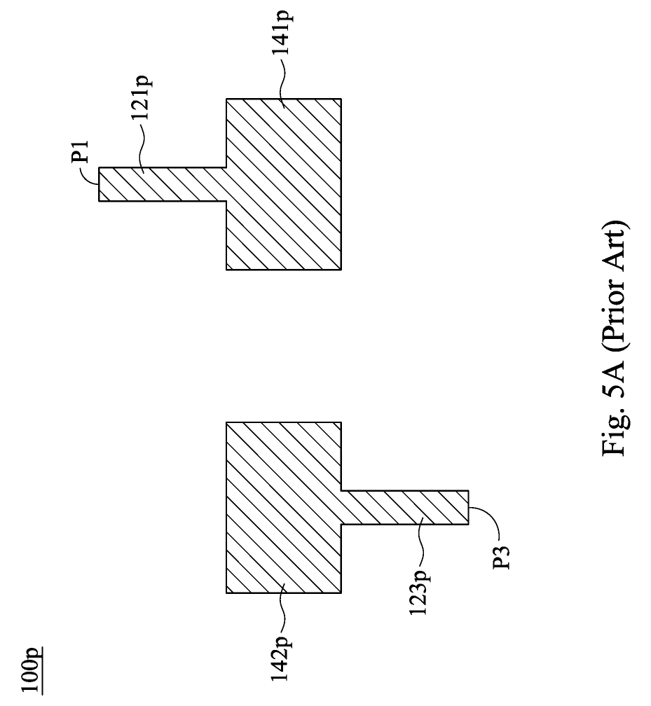

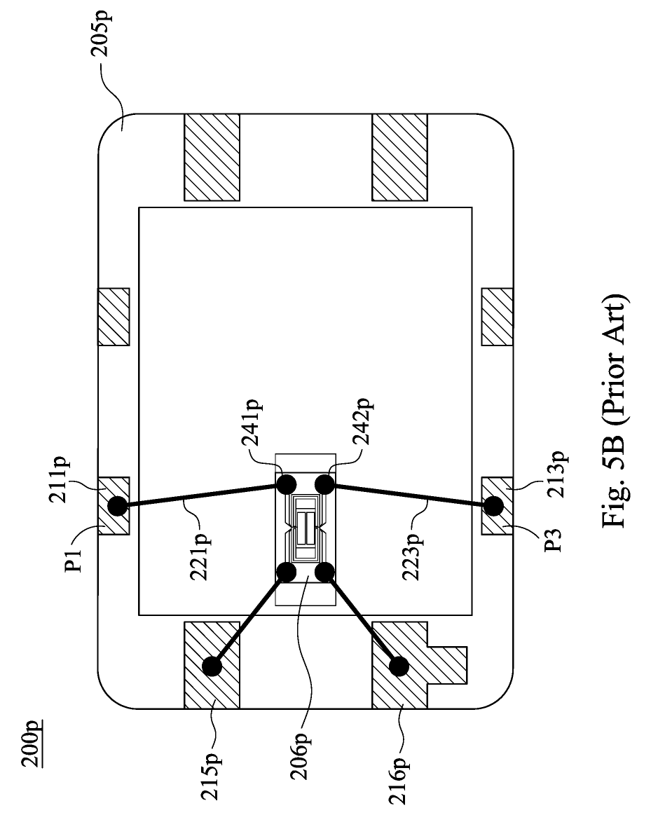

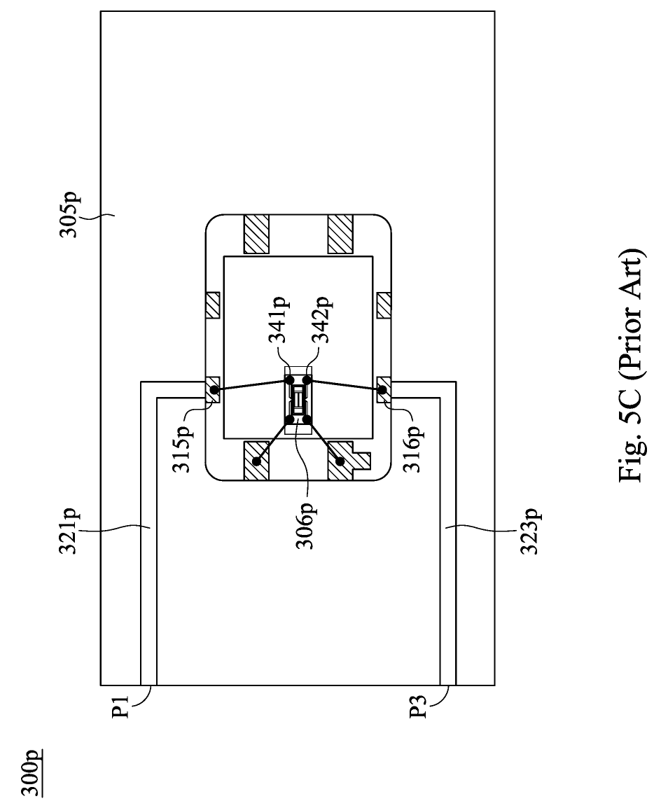

FIG. 5A is a schematic view of the conventional circuit element 100p. With reference to FIG. 5A, the conventional circuit element 100p has an input port P1 and an output port P3 and includes a first electrode 141p, a first connection line 121p, a second electrode 142p and a third connection line 123p. Compared with the conventional circuit element 100p in FIG. 5A, the circuit element 100 of the first embodiment of the present disclosure in FIG. 1A additionally includes at least the fourth connection line 124 and the first load 171, thereby facilitating suppression of feedthrough capacitance and lowering the admittance parameter of the stopband.

FIG. 1G is a schematic view of admittance parameters Y31 of the circuit element 100 in FIG. 1A and the conventional circuit element 100p in FIG. 5A. With reference to FIG. 1A, FIG. 1G and FIG. 5A, in the stopband, the admittance parameter Y31 of the conventional circuit element 100p in an air environment is lower than that in a deionized environment, and the admittance parameter Y31 of the circuit element 100 of the first embodiment of the present disclosure in the deionized environment is lower than that of the conventional circuit element 100p in the air environment. Furthermore, the stopband of the curve of the admittance parameter Y31 of the conventional circuit element 100p in the deionized environment is 3 dB lower than the peak value thereof, while the stopband of the curve of the admittance parameter Y31 of the circuit element 100 of the first embodiment of the present disclosure in the deionized environment is 25 dB lower than the peak value thereof, which has a difference between its stopband and peak value being much greater than that of the conventional circuit element 100p.

Furthermore, the circuit elements, electronic packaging elements and circuit board assemblies of the present disclosure are featured with stably reducing the feedthrough signal by about 20 dB over a wide frequency range while maintaining the amplitude required for the resonant signal (i.e., the target mode). When operating in a deionized liquid environment, the feedthrough level increases due to the dielectric constant of the liquid, while the resonant signal decreases due to the damping of the liquid, resulting in a stopband rejection ratio of approximately 3 dB in the deionized liquid environment. However, although the resonant signals of the circuit elements, electronic packaging elements and circuit board assemblies of the present disclosure are still affected by liquid damping, the significantly reduced feedthrough level ensures that the stopband suppression is better than that of the conventional technique in the air environment.

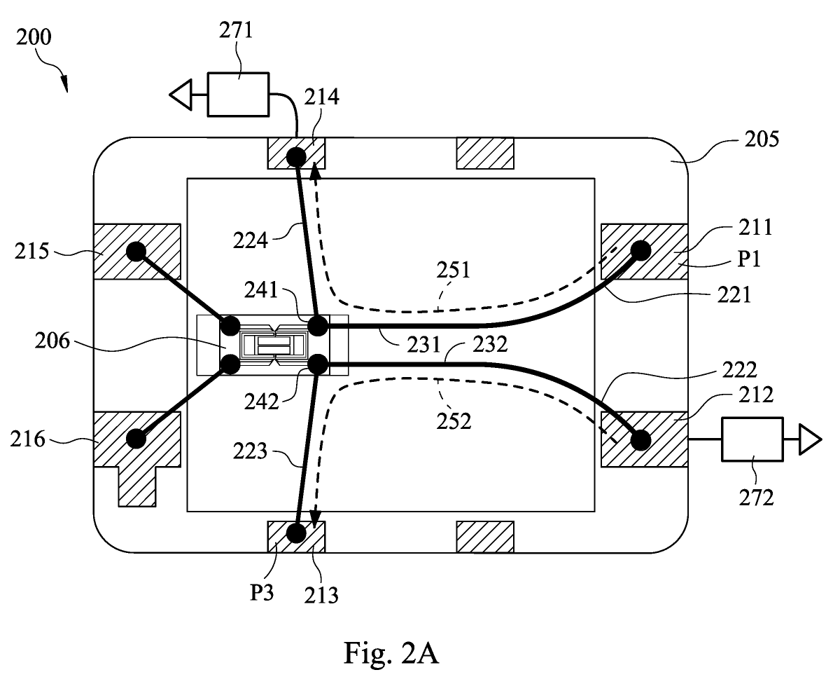

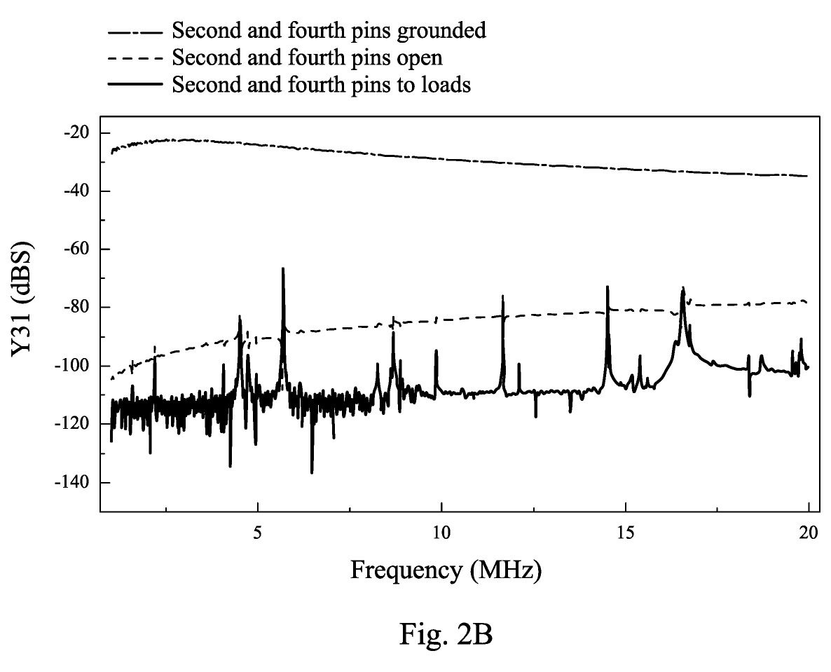

FIG. 2A is a schematic view of an electronic packaging element 200 according to the second embodiment of the present disclosure. With reference to FIG. 2A, the electronic packaging element 200 includes a packaging substrate 205, a chip 206, a first connection line 221, a fourth connection line 224, a first pin 211, a fourth pin 214, a third connection line 223 and a third pin 213. In addition, the electronic packaging element 200 can be served as a circuit element according to the present disclosure.

The chip 206 is disposed on the packaging substrate 205 and includes a first electrode 241 and a second electrode 242, and the second electrode 242 is separated from and coupled to the first electrode 241. The first connection line 221 is electrically connected to the first electrode 241. The fourth connection line 224 is electrically connected to the first electrode 241, and the first connection line 221 and the fourth connection line 224 are electrically connected to form a first path 251. The first pin 211 is disposed on the packaging substrate 205, and the first pin 211, the first connection line 221 and the first electrode 241 are electrically connected in sequence. The fourth pin 214 is disposed on the packaging substrate 205, and the first electrode 241, the fourth connection line 224 and the fourth pin 214 are electrically connected in sequence. The third connection line 223 is electrically connected to the second electrode 242, and the third connection line 223 is at least a part of a second path 252. The third pin 213 is disposed on the packaging substrate 205, and the second electrode 242, the third connection line 223 and the third pin 213 are electrically connected in sequence. The first pin 211, the third pin 213 and the fourth pin 214 are configured to be electrically connected to a circuit board (not shown in drawings), the first pin 211 and the third pin 213 are configured for respectively inputting a signal to the electronic packaging element 200 and outputting a signal therefrom, and at least one line segment 231 of the first path 251 and at least one line segment 232 of the second path 252 are not perpendicular to each other. Therefore, the electronic packaging element 200 including two coupling electrodes of the present disclosure is designed according to a feedthrough elimination method based on the interconnect magnetic effect, thereby reducing feedthrough signal of the electronic packaging element 200.

In detail, each of the first connection line 221, the third connection line 223 and the fourth connection line 224 may be a metal bonding wire. Therefore, the electronic packaging element 200 according to the present disclosure is advantageous in applicable to a conventional chip containing two coupling electrodes (e.g., the conventional circuit element 100p in FIG. 5A). Moreover, any of the first connection line, the second connection line, the third connection line and the fourth connection line in the circuit element, the electronic packaging element and the circuit board assembly according to the present disclosure may be a metal bonding wire, a conductive layout on a substrate, or a metal pin, and is not limited thereto.

The first pin 211, the first connection line 221, the first electrode 241, the fourth connection line 224 and the fourth pin 214 may be electrically connected in sequence. Therefore, it helps reduce feedthrough signal and simplify package design.

The electronic packaging element 200 may further include a second connection line 222 and a second pin 212. The second connection line 222 is electrically connected to the second electrode 242. The second pin 212 is disposed on the packaging substrate 205. The second pin 212, the second connection line 222 and the second electrode 242 are electrically connected in sequence, and the second connection line 222 and the third connection line 223 are electrically connected to form the second path 252. Therefore, it is advantageous in improving the application flexibility of the non-directional electronic packaging element 200.

The fourth pin 214 may be configured to be electrically connected to a first load 271 disposed on the circuit board, the second pin 212 may be configured to be electrically connected to a second load 272 disposed on the circuit board, and the electronic packaging element 200 is disposed on and electrically connected to the circuit board. Therefore, the feedthrough capacitance of the electronic packaging element 200 can be reduced by the non-perpendicular first path 251 and second path 252.

The at least one line segment 231 of the first path 251 and the at least one line segment 232 of the second path 252 may be parallel to each other, that is, an included angle (not labeled in drawings) between the at least one line segment 231 of the first path 251 and the at least one line segment 232 of the second path 252 may be 0 degrees. The at least one line segment 231 of the first path 251 is located on the first connection line 221, and the at least one line segment 232 of the second path 252 is located on the second connection line 222. Therefore, it is beneficial to improve the signal-to-background ratio and simplify package design.

Specifically, the electronic packaging element 200 may be a resonator. The chip 206 includes four pins, two of the pins are located at the first electrode 241 and a second electrode 242, respectively, and the other two of the pins are electrically connected to the ground pins 215, 216 of the electronic packaging element 200 via two metal bonding wires (not labeled in drawings). The input port P1 of the electronic packaging element 200 is located at the first pin 211, and the output port P3 thereof is located at the third pin 213. The first pin 211, the first connection line 221, the first electrode 241, the fourth connection line 224, the fourth pin 214 and the first load 271 are electrically connected in sequence, and the first connection line 221, the first electrode 241 and the fourth connection line 224 are electrically connected in sequence to form the first path 251. The second load 272, the second pin 212, the second connection line 222, the second electrode 242, the third connection line 223 and the third pin 213 are electrically connected in sequence, and the second connection line 222, the second electrode 242 and the third connection line 223 are electrically connected in sequence to form the second path 252.

FIG. 2B is a schematic view of admittance parameters Y31 of the electronic packaging element 200 in FIG. 2A, and FIG. 2B illustrates the curves of the admittance parameter Y31 for the second pin 212 and the fourth pin 214, being directly grounded (not electrically connected to the load), open circuit, and electrically connected to the second load 272 and the first load 271 (as shown in FIG. 2A), of the electronic packaging element 200. With reference to FIG. 2B, the electronic packaging element 200 in FIG. 2A according to the present disclosure is advantageous in unaffecting the peak value of the target mode and significantly reducing the admittance parameter Y31 of the stopband, i.e., reducing the feedthrough signal of the electronic packaging element 200.

FIG. 5B is a schematic view of a conventional electronic packaging element 200p. With reference to FIG. 5B, the conventional electronic packaging element 200p includes a packaging substrate 205p, a chip 206p, a first connection line 221p, a first pin 211p, a third connection line 223p and a third pin 213p, and the chip 206p is disposed on the packaging substrate 205p and includes a first electrode 241p and a second electrode 242p. Specifically, the chip 206p includes four pins, two of the pins are located at the first electrode 241p and the second electrode 242p, respectively, and the other two of the pins are electrically connected to the ground pins 215p, 216p of the conventional electronic packaging element 200p via two metal bonding wires. The input port P1 of the conventional electronic package element 200p is located at the first pin 211p, and the output port P3 thereof is located at the third pin 213p. The first pin 211p, the first connection line 221p and the first electrode 241p are electrically connected in sequence, and the second electrode 242p, the third connection line 223p and the third pin 213p are electrically connected in sequence.

Compared with the conventional electronic packaging element 200p in FIG. 5B, the electronic packaging element 200 of the second embodiment of the present disclosure additionally includes at least the fourth connection line 224 and the first load 271, which are electrically connected to the first electrode 241, and is reconfigured for the positions of the first pin 211 and the fourth pin 214, so that the at least one line segment 231 of the first path 251 and the at least one line segment 232 of the second path 252 are not perpendicular to each other, thereby facilitating suppression of feedthrough capacitance and lowering the admittance parameter of the stopband.

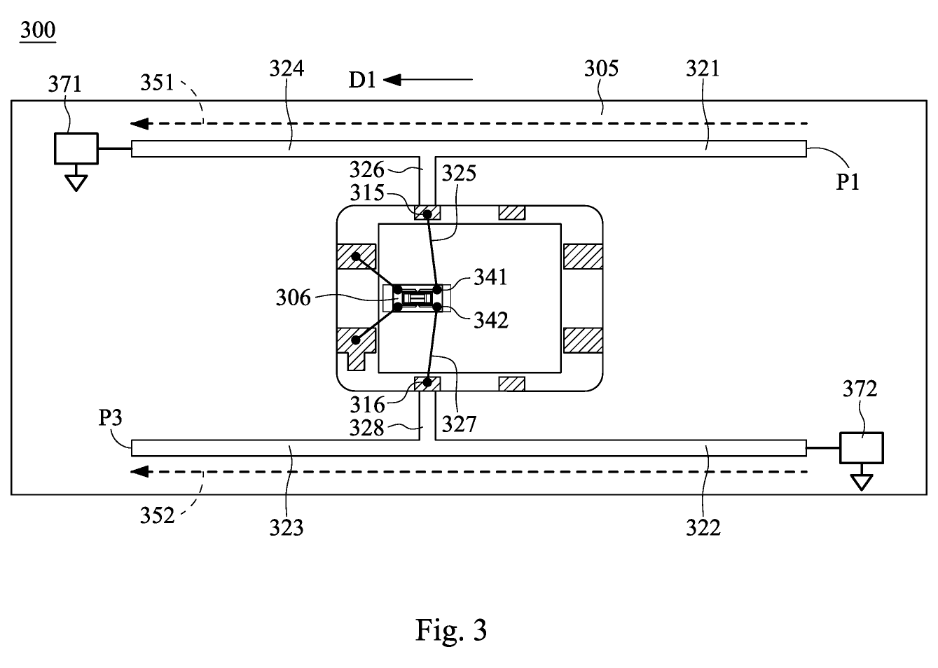

FIG. 3 is a schematic view of a circuit board assembly 300 according to the third embodiment of the present disclosure. With reference to FIG. 3, the circuit board assembly 300 includes a circuit board 305, a chip 306, a first connection line 321, a fourth connection line 324 and a third connection line 323. In addition, the circuit board assembly 300 can be served as a circuit element according to the present disclosure, and components and circuits unrelated to the present disclosure are omitted in FIG. 3.

The chip 306 is disposed on the circuit board 305 and includes a first electrode 341 and a second electrode 342, and the second electrode 342 is separated from and coupled to the first electrode 341. The first connection line 321 is electrically connected to the first electrode 341. The fourth connection line 324 is electrically connected to the first electrode 341, and the first connection line 321 and the fourth connection line 324 are electrically connected to form a first path 351. The third connection line 323 is electrically connected to the second electrode 342, and the third connection line 323 is at least a part of a second path 352. The first connection line 321, the third connection line 323 and the fourth connection line 324 are disposed on the circuit board 305. The first connection line 321 and the third connection line 323 are configured for respectively inputting a signal to the circuit board assembly 300 and outputting a signal therefrom. At least one line segment of the first path 351 and at least one line segment of the second path 352 are not perpendicular to each other. Therefore, the circuit board assembly 300 including two coupling electrodes of the present disclosure is designed according to a feedthrough elimination method based on the interconnect magnetic effect, thereby reducing feedthrough signal of the circuit board assembly 300.

In detail, the circuit board assembly 300 may further include a second connection line 322, which is disposed on the circuit board 305 and electrically connected to the second electrode 342. The second connection line 322 and the third connection line 323 are electrically connected to form the second path 352. Therefore, it is advantageous in improving the application flexibility of the non-directional circuit board assembly 300.

The circuit board assembly 300 may further include a first load 371 and a second load 372. The first load 371 is disposed on the circuit board 305, and the first connection line 321, the fourth connection line 324 and the first load 371 are electrically connected in sequence. The second load 372 is disposed on the circuit board 305, and the second load 372, the second connection line 322 and the third connection line 323 are electrically connected in sequence. Therefore, the feedthrough capacitance of the circuit board assembly 300 can be reduced by the non-perpendicular first path 351 and second path 352.

Specifically, the circuit board assembly 300 may be a printed circuit board assembly (PCBA) and include a resonator or a portion thereof. An included angle (not labeled in drawings) between the entire first path 351 and the entire second path 352 is 0 degrees, that is, the entire first path 351 and the entire second path 352 are parallel to each other. The circuit board assembly 300 has a first direction D1, the first connection line 321 is extended toward one end of the first direction D1, and the third connection line 323 is extended toward the other end of the first direction D1.

Moreover, the chip 306 may be packaged as a conventional electronic packaging element (e.g., the conventional electronic packaging element 200p in FIG. 5B), and the chip of the circuit board assembly of the present disclosure may be directly electrically connected to the circuit board without packaging (not shown in drawings). The conventional electronic packaging element of the circuit board assembly 300 includes pins 315, 316. Two pins of the chip 306 are located at the first electrode 341 and the second electrode 342, respectively. The first electrode 341, the connection line 325 and the pin 315 are electrically connected in sequence, the second electrode 342, the connection line 327 and the pin 316 are electrically connected in sequence, and the connection lines 325, 327 are metal bonding wires on the conventional electronic packaging element. The input port P1 is located at one end of the first connection line 321, and the output port P3 is located at one end of the third connection line 323. The first connection line 321, the second connection line 322, the third connection line 323, the fourth connection line 324 and the connection lines 326, 328 are conductive layout on the circuit board 305. One end of the connection line 326 is electrically connected to the pin 315, the other end of the connection line 326 is electrically connected to the first connection line 321 and the fourth connection line 324, and the first connection line 321 and the fourth connection line 324 extend from the other end of the connection line 326 in two opposite directions, respectively, of the first direction D1. One end of the connection line 328 is electrically connected to the pin 316, the other end of the connection line 328 is electrically connected to the second connection line 322 and the third connection line 323, and the second connection line 322 and the third connection line 323 extend from the other end of connection line 328 in two opposite directions, respectively, of the first direction D1.

FIG. 5C is a schematic view of a conventional circuit board assembly 300p. With reference to FIG. 5C, the conventional circuit board assembly 300p includes a circuit board 305p, a chip 306p, a first connection line 321p and a third connection line 323p. The chip 306p is disposed on a packaging board (not labeled in drawings) and includes a first electrode 341p and a second electrode 342p, the packaging board is disposed on the circuit board 305p and includes pins 315p, 316p, and the first connection line 321p and the third connection line 323p are conductive layout on the circuit board 305p. Specifically, the input port P1 is located at one end of the first connection line 321p, and the output port P3 is located at one end of the third connection line 323p. The first connection line 321p, the pin 315p and first electrode 341p are electrically connected in sequence, and the second electrode 342p, the pin 316p and third connection line 323p are electrically connected in sequence.

Compared with the conventional circuit board assembly 300p in FIG. 5C, the circuit board assembly 300 of the third embodiment of the present disclosure in FIG. 3 additionally includes at least the fourth connection line 324 and the first load 371, which are electrically connected to the first electrode 341, and is reconfigured for the conductive layout of the first connection line 321 and the fourth connection line 324, so that the at least one line segment of the first path 351 and the at least one line segment of the second path 352 are not perpendicular to each other, thereby facilitating suppression of feedthrough capacitance and lowering the admittance parameter of the stopband.

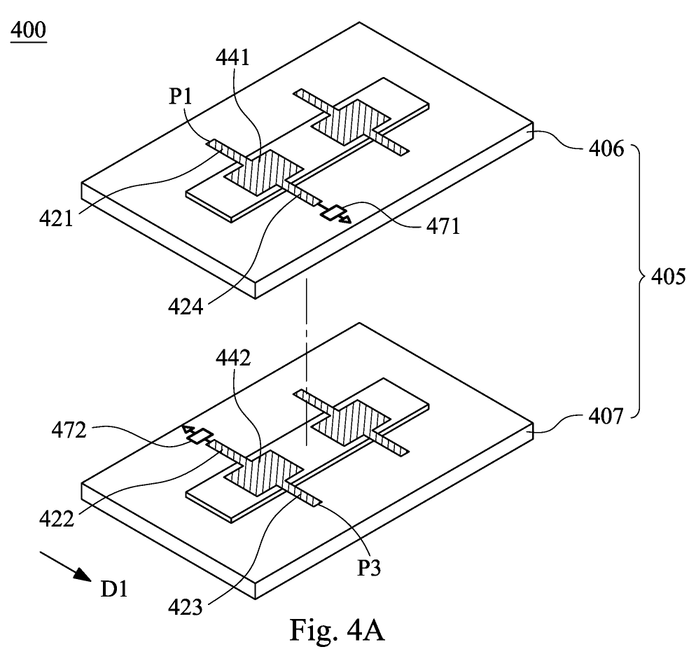

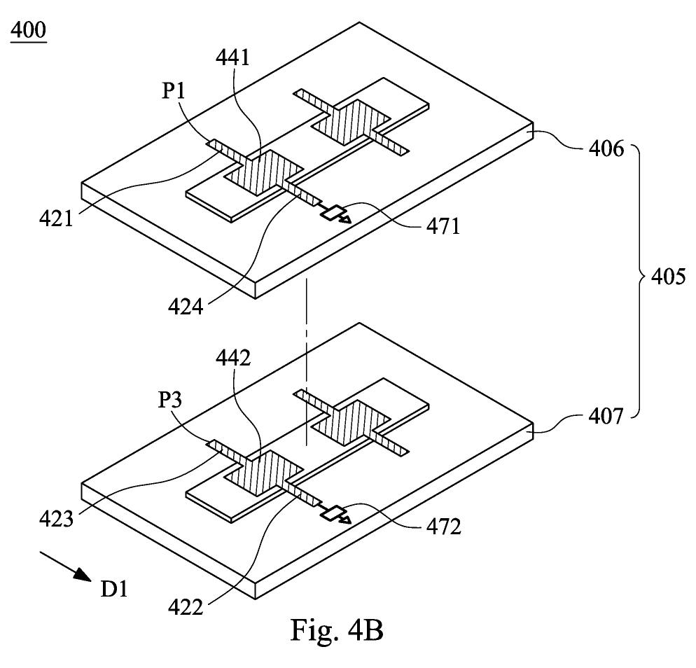

FIG. 4A is a schematic view of a circuit element 400 according to the first example of the fourth embodiment of the present disclosure, and FIG. 4B is a schematic view of a circuit element 400 according to the second example of the fourth embodiment of the present disclosure. With reference to FIG. 4A and FIG. 4B, the circuit element 400 in each of FIG. 4A and FIG. 4B includes a first electrode 441, a first connection line 421, a fourth connection line 424, a first load 471, a second electrode 442 and a third connection line 423.

The first connection line 421 is electrically connected to the first electrode 441. The fourth connection line 424 is electrically connected to the first electrode 441. The first connection line 421, the fourth connection line 424 and the first load 471 are electrically connected in sequence, and the first connection line 421 and the fourth connection line 424 are electrically connected to form a first path (not labeled in drawings). The second electrode 442 is separated from and coupled to the first electrode 441. The third connection line 423 is electrically connected to the second electrode 442, and the third connection line 423 is at least a part of a second path (not labeled in drawings). The first connection line 421 and the third connection line 423 are configured for respectively inputting a signal to the circuit element 400 and outputting a signal therefrom, and at least one line segment of the first path and at least one line segment of the second path are not perpendicular to each other. Therefore, the circuit element 400 including two coupling electrodes of the present disclosure is designed according to a feedthrough elimination method based on the interconnect magnetic effect, thereby reducing feedthrough signal of the circuit element 400.

In detail, an included angle between the entire first path and the entire second path is 0 degrees, that is, the entire first path and the entire second path are parallel to each other. The circuit element 400 may further include a second connection line 422 and a second load 472, and the second connection line 422 is electrically connected to the second electrode 442. The second load 472, the second connection line 422 and the third connection line 423 are electrically connected in sequence, and the second connection line 422 and the third connection line 423 are electrically connected to form the second path. The circuit element 400 further includes a substrate 405, which includes a first dielectric layer 406 and a second dielectric layer 407. The first connection line 421, the first electrode 441 and the fourth connection line 424 are electrically connected in sequence and conductive layout on the first dielectric layer 406. The second connection line 422, the second electrode 442 and the third connection line 423 are electrically connected in sequence and conductive layout on the second dielectric layer 407. Furthermore, in the embodiment according to the present disclosure, the first connection line, the first electrode and the fourth connection line are electrically connected in sequence and may be conductive layout on a substrate, and the second connection line, the second electrode and the third connection line are electrically connected in sequence and may be conductive layout on another substrate. There is an air gap between the substrate and the another substrate, and the greater the air gap, the smaller the effect of the circuit element configured as shown in FIG. 4A on reducing the feedthrough signal.

Specifically, the main difference between the circuit elements 400 in FIG. 4A and FIG. 4B lies in the placement of the second connection line 422, the third connection line 423 and the second load 472. In FIG. 4A, the second load 472 and the first load 471 are located at opposite ends of the first direction D1. In FIG. 4B, the second load 472 and the first load 471 are located at the same end of the first direction D1. The admittance parameter in the stopband of the circuit element 400 in FIG. 4A is lower than that of the circuit element 400 in FIG. 4B. Furthermore, since the induced current (e.g., the induced current ILenz in FIG. 1D) has directionality, the second load 472 and the first load 471 are disposed at opposite ends of the first direction D1 as shown in FIG. 4A, and the phase difference of the admittance parameter is +90 degrees. However, the common feedthrough signal generated by coupling is mostly capacitive (the phase difference of the admittance parameter is -90 degrees). Hence, the opposite setting of the second load 472 and the first load 471 helps to eliminate the feedthrough signal.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A circuit element, comprising:
a first electrode;
a first connection line electrically connected to the first electrode;
a fourth connection line electrically connected to the first electrode;
a first load, wherein the first connection line, the fourth connection line and the first load are electrically connected in sequence, and the first connection line and the fourth connection line are electrically connected to form a first path;
a second electrode separated from and coupled to the first electrode; and
a third connection line electrically connected to the second electrode, wherein the third connection line is at least a part of a second path;
wherein the first connection line and the third connection line are configured for respectively inputting a signal to the circuit element and outputting a signal therefrom, and at least one line segment of the first path and at least one line segment of the second path are not perpendicular to each other.

2. The circuit element of claim 1, wherein the circuit element is a resonator.

3. The circuit element of claim 1, wherein an included angle between the at least one line segment of the first path and the at least one line segment of the second path is between 0 degrees and 80 degrees.

4. The circuit element of claim 3, wherein the at least one line segment of the first path and the at least one line segment of the second path are parallel to each other.

5. The circuit element of claim 1, wherein the circuit element has a first direction, one end along the first direction of the first electrode is electrically connected to the first connection line, and the other end along the first direction of the second electrode is electrically connected to the third connection line.

6. The circuit element of claim 1, further comprising:
a substrate, wherein the first electrode, the second electrode, the first connection line, the third connection line and the fourth connection line are at least parts of a conductive layout on the substrate.

7. The circuit element of claim 1, further comprising:
a second connection line electrically connected to the second electrode; and
a second load, wherein the second load, the second connection line and the third connection line are electrically connected in sequence, and the second connection line and the third connection line are electrically connected to form the second path.

8. The circuit element of claim 7, wherein the first connection line, the first electrode, the fourth connection line and the first load are electrically connected in sequence, the first connection line, the first electrode and the fourth connection line form the first path, the second load, the second connection line, the second electrode and the third connection line are electrically connected in sequence, and the second connection line, the second electrode and the third connection line form the second path.

9. The circuit element of claim 1, wherein an equivalent resistance of the first load is between 10 ohm and 1000 ohm.

10. An electronic packaging element, comprising:
a packaging substrate;
a chip disposed on the packaging substrate and comprising a first electrode and a second electrode, wherein the second electrode is separated from and coupled to the first electrode;
a first connection line electrically connected to the first electrode;
a fourth connection line electrically connected to the first electrode, wherein the first connection line and the fourth connection line are electrically connected to form a first path;
a first pin disposed on the packaging substrate, wherein the first pin, the first connection line and the first electrode are electrically connected in sequence;
a fourth pin disposed on the packaging substrate, wherein the first electrode, the fourth connection line and the fourth pin are electrically connected in sequence;
a third connection line electrically connected to the second electrode, wherein the third connection line is at least a part of a second path; and
a third pin disposed on the packaging substrate, wherein the second electrode, the third connection line and the third pin are electrically connected in sequence;
wherein the first pin, the third pin and the fourth pin are configured to be electrically connected to a circuit board, the first pin and the third pin are configured for respectively inputting a signal to the electronic packaging element and outputting a signal therefrom, and at least one line segment of the first path and at least one line segment of the second path are not perpendicular to each other.

11. The electronic packaging element of claim 10, wherein each of the first connection line, the third connection line and the fourth connection line is a metal bonding wire.

12. The electronic packaging element of claim 10, wherein the first pin, the first connection line, the first electrode, the fourth connection line and the fourth pin are electrically connected in sequence.

13. The electronic packaging element of claim 10, further comprising:
a second connection line electrically connected to the second electrode; and
a second pin disposed on the packaging substrate, wherein the second pin, the second connection line and the second electrode are electrically connected in sequence, and the second connection line and the third connection line are electrically connected to form the second path.

14. The electronic packaging element of claim 13, wherein the fourth pin is configured to be electrically connected to a first load disposed on the circuit board, and the second pin is configured to be electrically connected to a second load disposed on the circuit board.

15. The electronic packaging element of claim 13, wherein the at least one line segment of the first path and the at least one line segment of the second path are parallel to each other.

16. The electronic packaging element of claim 13, wherein the at least one line segment of the first path is located on the first connection line, and the at least one line segment of the second path is located on the second connection line.

17. A circuit board assembly, comprising:
a circuit board;
a chip disposed on the circuit board and comprising a first electrode and a second electrode, wherein the second electrode is separated from and coupled to the first electrode;
a first connection line electrically connected to the first electrode;
a fourth connection line electrically connected to the first electrode, wherein the first connection line and the fourth connection line are electrically connected to form a first path; and
a third connection line electrically connected to the second electrode, wherein the third connection line is at least a part of a second path;
wherein the first connection line, the third connection line and the fourth connection line are disposed on the circuit board, the first connection line and the third connection line are configured for respectively inputting a signal to the circuit board assembly and outputting a signal therefrom, and at least one line segment of the first path and at least one line segment of the second path are not perpendicular to each other.

18. The circuit board assembly of claim 17, further comprising:
a second connection line disposed on the circuit board and electrically connected to the second electrode, wherein the second connection line and the third connection line are electrically connected to form the second path.

19. The circuit board assembly of claim 18, further comprising:
a first load disposed on the circuit board, wherein the first connection line, the fourth connection line and the first load are electrically connected in sequence; and
a second load disposed on the circuit board, wherein the second load, the second connection line and the third connection line are electrically connected in sequence.

20. The circuit board assembly of claim 17, wherein one end of a connection line is electrically connected to the first electrode, the other end of the connection line is electrically connected to the first connection line and the fourth connection line, and the first connection line and the fourth connection line extend from the other end of the connection line in two opposite directions, respectively, of a first direction.
